(19) United States
(12) Patent Application Publication
(10) Pub. No.: US 2014/0048951 A1
(43) Pub. Date: Feb. 20, 2014

(54) SEMICONDUCTOR ASSEMBLY WITH DUAL CONNECTING CHANNELS BETWEEN INTERPOSER AND CORELESS SUBSTRATE

(71) Applicant: Bridge Semiconductor Corporation, Taipei City (TW)

(72) Inventors: Charles W.C. LIN, Singapore (SG); Chia-Chung WANG, Hsinchu (TW)

(21) Appl. No.: 13/917,776

(22) Filed: Jun. 14, 2013

Related U.S. Application Data
(63) Continuation-in-part of application No. 13/615,819, filed on Sep. 14, 2012.
Application No. 13/615,819 is a continuation-in-part of application No. 13/753,625, filed on Jan. 30, 2013.
Application No. 13/753,625 is a continuation-in-part of application No. 13/615,819, filed on Sep. 14, 2012.
(60) Provisional application No. 61/682,801, filed on Aug. 14, 2012.
(60) Provisional application No. 61/682,801, filed on Aug. 14, 2012.

(51) Int. Cl. H01L 23/48

(52) U.S. Cl. CPC H01L 23/481
USPC 257/774

(57) ABSTRACT

A semiconductor assembly includes a semiconductor device, a through-via interposer, a coreless substrate and a stiffener. The semiconductor device is flip mounted on the interposer, and the interposer is affixed on the coreless substrate by adhesive and extends into an aperture of a stiffener which provides mechanical support for the coreless substrate. The electrically connection between the interposer and the coreless substrate includes bond wire and conductive micro-via. The coreless substrate can provide fan-out routing for the interposer.

### CROSS REFERENCE TO RELATED APPLICATION

This application is a continuation-in-part of U.S. application Ser. No. 13/615,819 filed Sep. 14, 2012 and a continuation-in-part of U.S. application Ser. No. 13/753,625 filed Jan. 30, 2013, each of which is incorporated by reference. U.S. application Ser. No. 13/753,625 filed Jan. 30, 2013 is a continuation-in-part of U.S. application Ser. No. 13/615,819 filed Sep. 14, 2012. U.S. application Ser. No. 13/615,819 filed Sep. 14, 2012 and U.S. application Ser. No. 13/753,625 filed Jan. 30, 2013 all claim the benefit of filing date of U.S. Provisional Application Ser. No. 61/682,801 filed Aug. 14, 2012.

### BACKGROUND OF THE INVENTION

1. Field of the Invention

The present invention relates to a semiconductor assembly, and more particularly to a semiconductor assembly with a semiconductor device flip mounted on an interposer which is affixed on a coreless substrate. The interposer has a through via and the interconnections between the interposer and the coreless substrate are flexibly retained by conductive micro-via and bond wire.

2. Description of Related Art

High performance semiconductor chips often incorporate a low-k dielectric as the interlayer material. As low-k dielectric material is porous, fragile and very sensitive to the interfacial stresses, conventional flip chip with laminate substrate often encounters various reliability and yield loss issues due to coefficient of thermal expansion (CTE) mismatch between the chip and the laminate substrate. In order to solve the problem, attempts to reduce interfacial stress by incorporating a CTE-matched interposer such as silicon in between chip and laminate substrate have been conducted. Moreover, as interposer can provide ultra-fine routing circuitries, attention has been drawn to dispose multiple chips on an interposer before connecting to the laminate substrate by through via for higher packing density and improved performance.

Furthermore, laminate substrate that provides mechanical support and signal routing for interposer typically includes a double-sided circuit board “core” with a number of “build-up” layers on each side of the core. The double-sided core uses multiple plated through holes for internal vertical connection, and the build-up layers has micro-vias for layer-to-layer connection. For example a 4-2-4 substrate indicates a two-layer core with four build up layers added to each side. In order to reduce the warpage of a package substrate, a core layer with a thickness of about 0.8-0.4 mm is normally used. Using thick core can reduce the warpage problem but is hardly feasible for a shorter routing length which is imperative for high performance requirements. Considerable development is therefore underway to solve this problem by developing coreless substrate with various types of re-enforced supports for minimal warpage.

Therefore, incorporating a through-via interposer which has a similar CTE to that of the silicon chip to resolve the yield and reliability concerns, and also using coreless substrate which does not have a core layer to improve the assembly's electrical performance would be high desirable.

U.S. Pat. No. 7,738,258 to Ohno et al., U.S. Pat. No. 8,183,678 to Lee et al., U.S. Pat. No. 8,379,400 to Sanuhara, U.S. Pat. No. 8,384,225 to Rahman et al., and U.S. Pat. No. 8,310,063 to Wang disclose an assembly in which silicon interposer with through via is stacked in between chip and laminate substrate for lateral and vertical interconnection. Although through silicon via in the interposer can improve system performance, the cross-talk between the through vias can become a limiting factor when via density becomes very high. Furthermore, small via diameter and high via density can lead to increased production costs due to low yield, which can make a product prohibitively expensive.

U.S. Pat. No. 6,570,248 and U.S. Pat. No. 6,281,042 to Ahn et al., U.S. Pat. No. 7,750,452 to Do et al., and U.S. Pat. No. 8,263,434 to Pagaila et al., disclose assembly structures that include a silicon interposer in a cavity of a substrate. A plurality of vias which are micro-machined through the silicon interposer serve the purpose to couple various semiconductor devices located on the opposing surfaces of the silicon interposer. This structure promises a superior electrical performance between the attached devices, but the traditional wire bonding technology which connects the interposer to the laminate substrate suffers limitations in performance and can only accommodate lower pin count modules. Furthermore, as silicon has a different coefficient of thermal expansion (CTE) to that of the resin substrate and the interposer is barely adhered to the surrounded substrate from the sidewalls, fragile due to inadequate support and prone to crack during thermal cycling due to thin and brittle nature of the interposer make this structure prohibitively unreliable for practical usage.

U.S. Pat. No. 7,902,660 to Lee et al., U.S. Pat. No. 7,754,598 to Lin et al., U.S. Pat. No. 8,227,703 to Maruyama et al., U.S. Patent Application No. 2012/0005887 to Mortensen et al., and U.S. Patent Application No. 2012/0074209 to Wu et al., disclose various structures of coreless substrate for packaging applications. Some coreless substrates may have acceptable co-planarity through material enhancements or structure modification, warpage often occurs again when substrate dimension reaches certain size or when substrate under high heat treatments during assembly processes. For example, when packaging a semiconductor chip of more than 10 mm square size, after solder reflows, the coplanarity of the substrate may increase to more than 30 um which is not acceptable for many packaging requirements.

U.S. Pat. No. 7,605,476 to Gritti, U.S. Pat. No. 7,663,245 to Lim, U.S. Pat. No. 8,372,692 to Liou et al., and U.S. Pat. No. 7,309,913 to Shim et al. disclose an assembly structure that has an interposer stacked between semiconductor chip and package substrate. Since the interposer does not have a through-via that can provide the shortest routing in vertical direction, signal integrity of the assembled devices can be adversely affected when the system requires high frequency transmitting or receiving of signals.

Despite numerous assembly architectures using active or passive interposers reported in the literature, many performance or reliability deficiencies remain. For instance, the solder connection in between silicon interposer and the package substrate can suffer reliability problem even with resin material under-filled in between to provide some interfacial re-enforcement.

### SUMMARY OF THE INVENTION

The present invention has been developed in view of such a situation, and an object thereof is to provide a semiconductor assembly in which a semiconductor device is flip mounted on an interposer which is affixed on a coreless substrate for mechanical support. The interposer and the coreless substrate are further supported by a stiffener; warp and bend of the assembly can be suppressed. The stiffener has an aperture and the interposer extends into the aperture of the stiffener and is electrically connected to the coreless substrate. The electrical connection between the interposer and the coreless substrate is flexibly retained by a combination of one or more conductive through-vias in the interposer and one or more conductive micro-vias in the coreless substrate, as well as one or more mechanically-formed bond wires to the coreless substrate directly so that the number of the conductive through-via in the interposer can be reduced and balanced by the bond wires according to system requirements, resulting in enhanced assembly yield and affordable cost. For instance, power/ground I/Os of the semiconductor device can be connected by the conductive through-via while signal I/Os can be connected by the bond wire or vice versa. Accordingly, the present invention provides a hybrid wiring board and a semiconductor assembly that includes a semiconductor device electrically connected to the hybrid wiring board, wherein the hybrid wiring board includes an interposer, a coreless substrate, and a stiffener.

In a preferred embodiment, the semiconductor device such as microprocessor, controller or memory chip can be flip mounted on the first surface of the interposer by an array of bumps. However, in most cases, more than one chip may be needed to be interconnected on the interposer. For example, one logic chip may be connected to four memory chips for fast data access, or an array of partitioned logic chips connected to each other on the interposer for lower cost compared to fabricating a single large chip. The bump can be a solder, gold or copper pillar coated with solder and the selection may depend on the pitch requirement. For instance, for a very fine pitch device, a copper pillar bump coated with solder is preferred because it allows minimal solder collapse during reflow to avoid solder bridging.

The interposer can be made of silicon, ceramic or glass with a plurality of contact pads formed on two opposite surfaces. More specifically, the interposer can include a plurality of first contact pads and one or more bond fingers on the first surface that faces the first vertical direction and a plurality of second contact pads on the second surface that faces the second vertical direction. The first contact pad on the first surface may be electrically connected to a corresponding second contact pad on the second surface by a vertical connecting element (such as conductive through-via). Alternatively, the first contact pad on the first surface may be electrically connected to the bond finger on the first surface by a lateral routing circuitry formed in the interposer. The routing circuitry in the interposer may have one or more routing layers and can serve to distribute signal from one location to another in lateral directions. Therefore, a portion of the first contact pads may be vertically connected to the second contact pads on the second surface by conductive through-vias while another portion of the first contact pads may be connected to the bond fingers on the first surface by routing circuitry. Accordingly, after flip chip assembly where the semiconductor device is coupled to the first contact pads of the interposer, the I/O pad of the flip mounted semiconductor device may be routed to the second contact pad of the interposer by conductive through-vias followed by micro-via connection to the coreless substrate or it may be routed to the bond finger which is electrically connected to the coreless substrate by a bond wire instead of the conductive through-vias in the interposer. More specifically, the first contact pad within the peripheral edges of the flip chip may transmit/receive an electrical signal from the routing circuitry, conductive through-via and second contact pad, or it may transmit/receive signal from the routing circuitry, bond finger and bond wire. Although the present embodiment depicts the interposer as an inactive device, it is to be understood that the interposer can include a transistor that has been integrated in the interposer such that the interposer becomes an active semiconductor device.

The bond wire can be made of gold, aluminum or copper or their alloys. The bond wire which serves as a connection channel between the interposer and the coreless substrate can have one end in contact with the bond finger of the interposer and the other end in contact with a bond pad of the coreless substrate.

The bond pad of the coreless substrate can be made of metal. For instance, the bond pad can consist essentially of copper and be coated by nickel, palladium, gold or their alloys for bonding purpose. The bond pad can be exposed from the coreless substrate surface in the first vertical direction and be aligned with and extend to the aperture of the stiffener. More specifically, the bond pad can be laterally aligned with and laterally extend between peripheral edges of the interposer and side walls of the aperture of the stiffener in lateral directions. The bond pad is electrically connected to the bond finger of the interposer by the bond wire and can also be electrically connected to the routing circuitry of the coreless substrate by the conductive micro-via residing in the coreless substrate.

The coreless substrate can cover the interposer and the stiffener in the second vertical direction and include one or more bond pads, a first dielectric layer and one or more first conductive traces. For instance, the first dielectric layer covers the interposer, the bond pad and the stiffener in the second vertical direction and can extend to peripheral edges of the assembly. The first dielectric layer includes one or more first micro-via openings that are disposed adjacent to the bond pads and the second contact pads of the interposer and optionally adjacent to the stiffener. One or more first conductive traces are disposed on the first dielectric layer (i.e. extend from the first dielectric layer in the second vertical direction and extend laterally on the first dielectric layer) and extend into the first micro-via openings in the first vertical direction to form one or more conductive micro-vias that electrically connect the bond pads and the second contact pads, thereby providing signal routing for the bond pads and the second contact pads of the interposer and optionally providing electrical connections for the stiffener. Specifically, the first conductive traces can directly contact the bond pads and the second contact pads to provide signal routing for the interposer, and thus the electrical connection between the interposer and the coreless substrate can be in dual channels and can be devoid of solder. The first conductive traces can also directly contact the stiffener for grounding or electrical connections to passive components such as thin film resistors or capacitors deposited thereon.

The coreless substrate can include additional layers of dielectric, additional layers of micro-via openings, and additional layers of conductive traces if needed for further signal routing. For instance, the coreless substrate can further include a second dielectric layer, one or more second micro-via openings and one or more second conductive traces. The second dielectric layer with one or more second micro-via openings disposed therein is disposed on the first dielectric layer and the first conductive traces (i.e. extends from the first dielectric insulating layer and the first conductive traces in the second vertical direction) and can extend to peripheral edges of the assembly. The second micro-via openings are disposed adjacent to the first conductive traces. One or more second conductive traces are disposed on the second dielectric layer (i.e. extend from the second dielectric layer in the second vertical direction and extend laterally on the second dielectric layer) and extend into the second micro-via openings in the first vertical direction to provide electrical connections for the first conductive traces. Furthermore, the first micro-via openings and the second micro-via openings can have the same size, and the first dielectric layer, the first conductive traces, the second dielectric layer and the second conductive traces can have flat elongated surfaces that face in the second vertical direction.

The coreless substrate can include one or more interconnect pads to provide electrical contacts for the next level assembly such as mother board and/or another electronic device such as a semiconductor chip, or another semiconductor assembly like BGA. The interconnect pads can extend to or beyond the first conductive traces in the second vertical direction and include an exposed contact surface that faces in the second vertical direction. For instance, the interconnect pad can be adjacent to and integral with the second conductive trace. In addition, the first conductive trace and the second conductive trace can provide an electrical interconnection between the interconnect pad, bond pad and the second contact pad of the interposer. As a result, the electrical contacts (i.e. the first contact pads of the interposer and the interconnect pads of the coreless substrate) can be electrically connected to one another and located on opposite surfaces that face in opposite vertical directions so that one or more semiconductor chips can be flip mounted on for a semiconductor assembly.

The stiffener has an aperture and can extend to peripheral edges of the assembly to provide mechanical support for the coreless substrate and the interposer and can be a single layer structure or a multi-layer structure (such as a circuit board or a multi-layer ceramic board or a laminate of a substrate and a conductive layer). The stiffener can be made of ceramics, metal or other various inorganic materials, such as aluminum oxide (Al₂O₃), aluminum nitride (AlN), silicon nitride (SiN), silicon (Si), copper (Cu), copper alloys (e.g., Cu/Mo/Cu), aluminum (Al), stainless steel, etc. The stiffener can also be made of organic materials such as copper-clad laminate.

The coreless substrate of the present invention can further include a stopper. The stopper can serve as a placement guide for the interposer and be in close proximity to and laterally aligned with and laterally extends between peripheral edges of the interposer and the bond pad in the lateral directions, so as to prevent the interposer from undesirable movement during interposer attachment. In any case, the interposer and the stopper can be aligned with and extend into the aperture of the stiffener. The stopper can be made of a metal such as copper, aluminum, nickel, iron, tin or their alloys.

The coreless substrate of the present invention can further include a placement guide. The placement guide for the stiffener can be in close proximity to and laterally aligned with and laterally extend beyond the outer peripheral edges of the stiffener in lateral directions. Like the stopper, the placement guide for the stiffener can be made of a metal such as copper, aluminum, nickel, iron, tin or their alloys.

The stopper, the placement guide and the bond pad can contact and extend from the first dielectric layer of the coreless substrate in the first vertical direction and can be simultaneously formed with the same material such as copper. Moreover, the stopper and the placement guide can have patterns against undesirable movement of the interposer and the stiffener, respectively. For instance, the stopper and the placement guide can include a continuous or discontinuous strip or an array of posts. The stopper and the placement guide can have the same or different patterns. Specifically, the stopper can be laterally aligned with four lateral surfaces of the interposer to stop the lateral displacement of the interposer. For instance, the stopper can be aligned along and conform to four sides, two diagonal corners or four corners of the interposer and a gap in between the interposer and the stopper preferably is in a range of about 0.001 to 1 mm. The interposer can be spaced from the inner wall of the aperture by the stopper and the bond pad, and a bonding material can be added between the interposer and the stiffener to enhance rigidity. Likewise, the placement guide can be laterally aligned with four outer lateral surfaces of the stiffener to stop the lateral displacement of the stiffener. For instance, the placement guide can be aligned along and conform to four outer sides, two outer diagonal corners or four outer corners of the stiffener and a gap in between the outer peripheral edges of the stiffener and the placement guide preferably is in a range of about 0.001 to 1 mm. Besides, the stopper and the placement guide preferably have a thickness in a range of 10-200 microns.

The interposer and the stiffener can be affixed and mechanically connected to the first dielectric layer of the coreless substrate using an adhesive. The adhesive can contact the interposer, the stiffener, the stopper, the placement guide and the first dielectric layer and is sandwiched between the interposer and the coreless substrate and between the stiffener and the coreless substrate. In any case, the adhesive can be coplanar with the stopper, the placement guide and the bond pad in the second vertical direction and lower than the stopper, the placement guide and the bond pad in the first vertical direction. As the adhesive underneath the interposer and the stiffener is lower than the stopper and the placement guide in the first vertical direction, the stopper and the placement guide can stop the undesirable movement of the interposer and the stiffener during adhesive curing.

The present invention can also provide a three-dimensional semiconductor assembly in which the interposer is an active semiconductor device. In this approach, a first semiconductor device such as chip can be electrically connected to the first contact pads of the interposer such as a semiconductor chip that is exposed from the aperture of the stiffener using a wide variety of connection media including gold, solder or copper pillar bumps.

The present invention has numerous advantages. The conductive through via in the interposer can improve power stability of the attached chip. The bond wire can provide alternative interconnection pathway between the interposer and the coreless substrate in addition to the through via residing in the interposer, thereby reducing the number of through-via needed for the interposer. As such, the size of the interposer may be reduced, or the fabrication yield of the through-via can be improved due to lower density of the through-via in the interposer. Therefore, adding bond wire can significantly reduce the cost of the interposer and hence the semiconductor assembly. The stopper of the coreless substrate can accurately confine the placement location of the interposer and avoid the electrical connection failure between the interposer and the coreless substrate resulted from the lateral displacement of the interposer, thereby improving the manufacturing yield greatly. The direct electrical connection without solder between the interposer and the coreless substrate is advantageous to high I/O, high performance and high reliability. The stiffener can provide a power/ground plane, a heat sink and a robust mechanical support for the interposer and the coreless substrate. The semiconductor assembly using the same is reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1A-1J are cross-sectional views showing a method of making a semiconductor assembly that includes an interposer, a semiconductor chip, a stiffener and a coreless substrate electrically connected to the interposer in accordance with an embodiment of the present invention;

FIG. 1K is a cross-sectional view of a three-dimensional assembly that includes semiconductor devices attached to both sides of a hybrid wiring board in accordance with an embodiment of the present invention; and

FIG. 2 is a cross-sectional view showing a three-dimensional assembly with additional interconnection between the stiffener and the coreless substrate and a heat dissipating plate attached on the semiconductor chip and the stiffener in accordance with another embodiment of the present invention.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

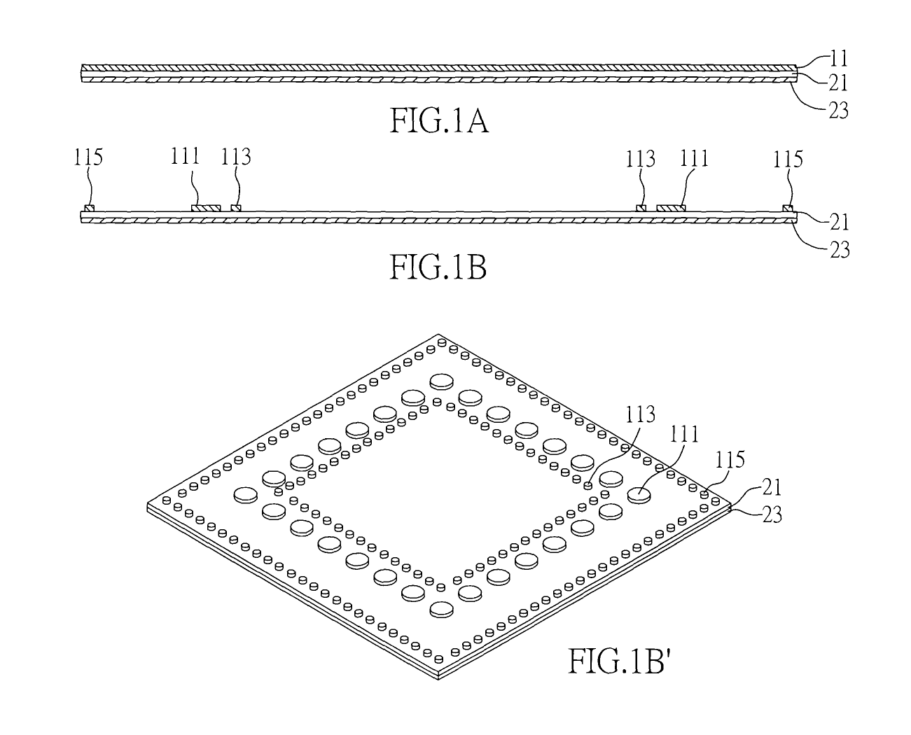

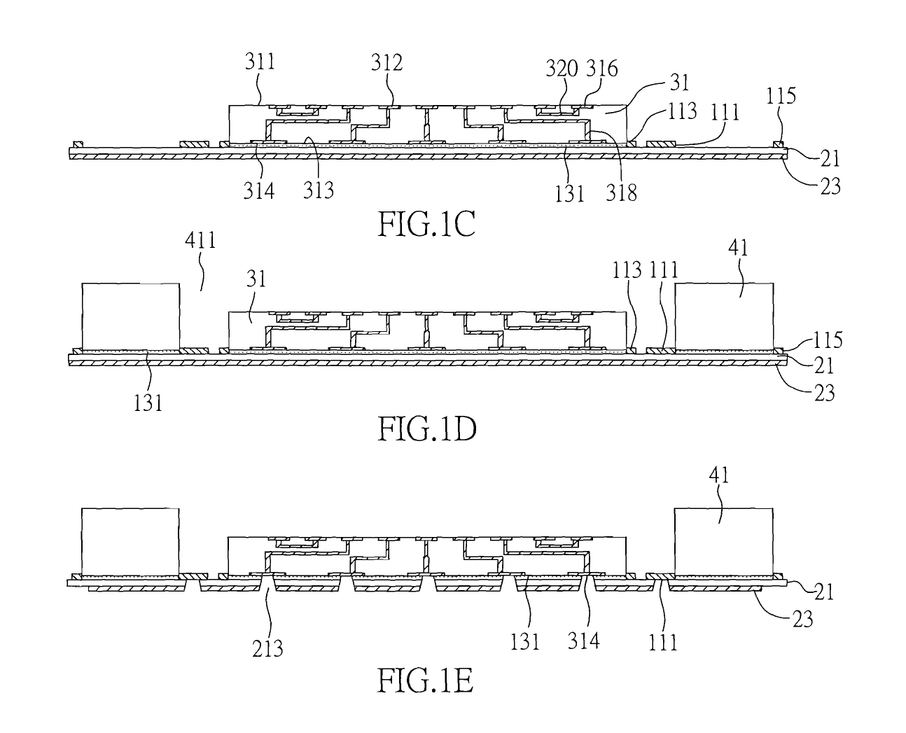

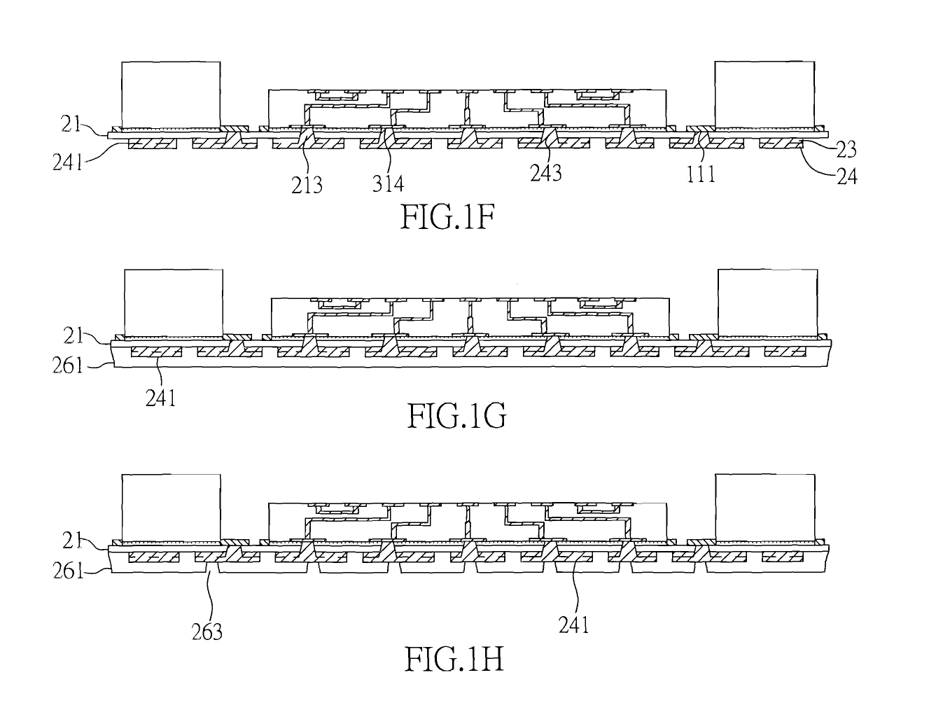

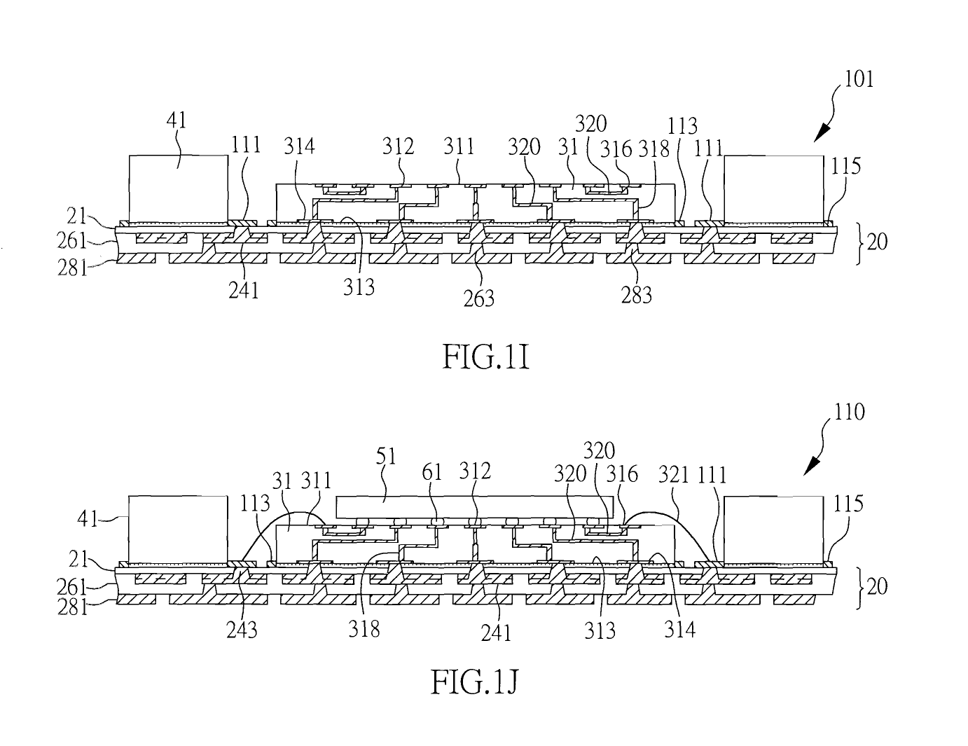

FIGS. 1A-1J are cross-sectional views showing a method of making a semiconductor assembly that includes an interposer, a semiconductor chip, a stiffener and coreless substrate electrically connected to the interposer by bond wires and conductive micro-vias in accordance with an embodiment of the present invention.

As shown in FIG. 1J, semiconductor assembly 110 includes interposer 31, stiffener 41, semiconductor chip 51, coreless substrate 20 and bond wires 321. Interposer 31 includes first surface 311, second surface 313 opposite to first surface 311, first contact pads 312 and bond fingers 316 at first surface 311, second contact pads 314 at second surface 313, conductive through-vias 318 that electrically connect portions of first contact pads 312 and second contact pads 314, and lateral routing circuitries 320 that electrically connect the bond fingers 316 and the portions of first contact pads 312. Interposer 31 can be a silicon interposer, a glass interposer or a ceramic interposer that contains a pattern of traces that fan out from a fine pitch at portions of first contact pads 312 to a coarse pitch at second contact pads 314, and further contains a pattern of traces that laterally extend from portions of first contact pads 312 to bond fingers 316. Coreless substrate 20 is electrically connected to interposer 31 and includes bond pads 111, stopper 113, placement guide 115, first dielectric layer 21, first conductive traces 241, second dielectric layer 261 and second conductive traces 281. Stopper 113 extends from first dielectric layer 21 in the upward direction and is in close proximity to peripheral edges of interposer 31. Bond pads 111, stopper 113 and interposer 31 are aligned with and extend into aperture 411 of stiffener 41.

FIG. 1A is a cross-sectional view of a laminate substrate that includes metal layer 11, first dielectric layer 21 and support plate 23. Metal layer 11 is illustrated as a copper layer with a thickness of 35 microns. However, metal layer 11 can also be made of other various metal materials and is not limited to a copper layer. Besides, metal layer 11 can be deposited on first dielectric layer 21 by numerous techniques including lamination, electroplating, electroless plating, evaporating, sputtering, and their combinations as a single layer or multiple layers, and preferably has a thickness in a range of 10 to 200 microns.

First dielectric layer 21 typically is made of epoxy resin, glass-epoxy, polyimide and the like and has a thickness of 50 microns. In this embodiment, first dielectric layer 21 is sandwiched between metal layer 11 and support plate 23. However, support plate 23 may be omitted in some embodiments. Support plate 23 typically is made of copper, but copper alloys or other materials are also doable. The thickness of support plate 23 can range from 25 to 1000 microns, and preferably ranges from 35 to 100 microns in consideration of process and cost. In this embodiment, support plate 23 is illustrated as a copper plate with a thickness of 35 microns.

FIGS. 1B and 1B′ are cross-sectional and top views, respectively, of the structure with bond pads 111, stopper 113, and placement guide 115 formed on first dielectric layer 21. Bond pads 111, stopper 113, and placement guide 115 can be formed by removing selected portions of metal layer 11 using photolithography and wet etching. In this illustration, as shown in FIG. 1B′, stopper 113 consists of plural metal posts in a rectangular frame array and conforms to four sides of an interposer subsequently disposed on first dielectric layer 21. Likewise, placement guide 115 consists of plural metal posts in a rectangular frame array and conforms to four sides of a stiffener 41 subsequently disposed on first dielectric layer 21. However, stopper 113 and placement guide 115 patterns are not limited thereto and can be other various patterns against undesirable movement of the subsequently disposed interposer and stiffener. For instance, stopper 113 and placement guide 115 also can consist of a continuous or discontinuous strip, and can be in an arrangement that conforms to four sides, two diagonal corners or four corners of a subsequently disposed interposer and stiffener. In addition, it is adopted to omit stopper 113 and placement guide 115, but stopper 113 and placement guide 115 are preferred in consideration of subsequent placement accuracy.

FIG. 1C is a cross-sectional view of the structure with interposer 31 mounted on first dielectric layer 21 using adhesive 131. Interposer 31 includes first surface 311, second surface 313 opposite to first surface 311, first contact pads 312 and bond fingers 316 at first surface 311, second contact pads 314 at second surface 313, conductive through-vias 318 that electrically connect the portions of first contact pads 312 and the second contact pads 314, and lateral routing circuitries 320 that electrically connect the bond fingers 316 and the portions of first contact pads 312. Interposer 31 can be a silicon interposer, a glass interposer or a ceramic interposer that contains a pattern of traces that fan out from a fine pitch at portions of first contact pads 312 to a coarse pitch at second contact pads 314, and further contains a pattern of traces that laterally extend from portions of first contact pads 312 to bond fingers 316.

Stopper 113 can serve as a placement guide for interposer 31, and thus interposer 31 is precisely placed at a predetermined location with its second surface 313 facing first dielectric layer 21. Stopper 113 extends from first dielectric layer 21 beyond second surface 313 of interposer 31 in the upward direction and is laterally aligned with and laterally extends beyond four sides of interposer 31 in the lateral directions. As stopper 113 is in close proximity to and conforms to four lateral surfaces of interposer 31 in lateral directions and adhesive 131 under interposer 31 is lower than stopper 113, any undesirable movement of interposer 31 due to adhesive curing can be avoided. Preferably, a gap in between interposer 31 and stopper 113 is in a range of about 0.001 to 1 mm.

FIG. 1D is a cross-sectional view of the structure with stiffener 41 mounted on first dielectric layer 21 using adhesive 131. Interposer 31, stopper 113, and bond pads 111 are aligned with and inserted into aperture 411 of stiffener 41. Aperture 411 is formed by laser cutting through stiffener 41 and can be formed with other techniques such as punching and mechanical drilling. Stiffener 41 is illustrated as a ceramic sheet with a thickness of about 0.6 mm, but also can be single layer or multi-layer structures, such as a multi-layer circuit board, a glass sheet or a metal sheet.

Interposer 31 and the inner wall of aperture 411 are spaced from one another by stopper 113 and bond pads 111. In this illustration, stiffener 41 can be precisely placed at a predetermined location through placement guide 115 that extends from first dielectric layer 21 beyond the attached surface of stiffener 41 in the upward direction and laterally extends beyond and is laterally aligned with four outer peripheral edges of stiffener 41, and adhesive 131 under stiffener 41 is lower than placement guide 115. As placement guide 115 is in close proximity to and conforms to four outer lateral surfaces of stiffener 41 in lateral directions and adhesive 131 under stiffener 41 is lower than placement guide 115, any undesirable movement of stiffener 41 due to adhesive curing can be avoided. Preferably, a gap in between the outer peripheral edges of stiffener 41 and placement guide 115 is in a range of about 0.001 to 1 mm.

FIG. 1E is a cross-sectional view of the structure showing first micro-via openings 213 formed through support plate 23, first dielectric layer 21, and adhesive 131 to expose second contact pads 314 and bond pads 111. First micro-via openings 213 may be formed by numerous techniques including laser drilling, plasma etching, and photolithography. Laser drilling can be enhanced by a pulsed laser. Alternatively, a scanning laser beam with a metal mask can be used. For instance, copper can be etched first to create a metal window followed by laser. First micro-via openings 213 typically have a diameter of 50 microns. Referring now to FIG. 1F, first conductive traces 241 are formed on first dielectric layer 21 by depositing plated layer 24 on support plate 23 and into first micro-via openings 213 and then patterning support plate 23 and plated layer 24 thereon. Alternatively, in some embodiments which apply a laminate substrate without support plate 23 or remove support plate 23 after the step illustrated in FIG. 1D, the first dielectric layer 21 can be directly metallized to form first conductive traces 241 after forming first micro-via openings 213.

Plated layer 24 can be deposited by numerous techniques including electroplating, electroless plating, evaporating, sputtering, and their combinations as a single layer or multiple layers. For instance, plated layer 24 is deposited by first dipping the structure in an activator solution to render first dielectric layer 21 catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, support plate 23 and plated layer 24 can be patterned to form first conductive traces 241 by numerous techniques including wet etching, electro-chemical etching, laser-assist etching, and their combinations with an etch mask (not shown) thereon that defines first conductive traces 241. Accordingly, first conductive traces 241 extend from first dielectric layer 21 in the downward direction, extend laterally on first dielectric layer 21 and extend into first micro-via openings 213 in the upward direction to form conductive micro-vias 243 in electrical contact with second contact pads 314 and bond pads 111.

Support plate 23 and plated layer 24 thereon are shown as a single layer for convenience of illustration. The boundary (shown in phantom) between the metal layers may be difficult or impossible to detect since copper is plated on copper. However, the boundary between plated layer 24 and first dielectric layer 21 is clear.

FIG. 1G is a cross-sectional view of the structure showing second dielectric layer 261 disposed on first conductive traces 241 and first dielectric layer 21. Second dielectric layer 261 can be epoxy resin, glass-epoxy, polyimide and the like deposited by numerous techniques including film lamination, spin coating, roll coating, and spray-on deposition and typically has a thickness of 50 microns. Preferably, first dielectric layer 21 and second dielectric layer 261 are the same material.

FIG. 1H is a cross-sectional view of the structure showing second micro-via openings 263 formed through second dielectric layer 261 to expose selected portions of first conductive traces 241. Like first micro-via openings 213, second micro-via openings 263 can be formed by numerous techniques including laser drilling, plasma etching and photolithography and typically have a diameter of 50 microns. Preferably, first micro-via openings 213 and second micro-via openings 263 are of the same size.

Referring now to FIG. 1I, hybrid wiring board 101 is accomplished with second conductive traces 281 formed on second dielectric layer 261. Hybrid wiring board 101 includes interposer 31, stiffener 41 and coreless substrate 20. In this illustration, coreless substrate 20 includes stopper 113, bond pads 111, placement guide 115, and build-up circuitry that includes first dielectric layer 21, first conductive traces 241, second dielectric layer 261 and second conductive traces 281. Second conductive traces 281 extend from second dielectric layer 261 in the downward direction, extend laterally on second dielectric layer 261 and extend into second micro-via openings 263 in the upward direction to form second conductive micro-vias 283 in electrical contact with first conductive traces 241.

Second conductive traces 281 can be deposited as a conductive layer by numerous techniques including electrolytic plating, electroless plating, sputtering, and their combinations and then patterned by numerous techniques including wet etching, electro-chemical etching, laser-assist etching, and their combinations with an etch mask (not shown) thereon that defines second conductive traces 281. Preferably, first conductive traces 241 and second conductive traces 281 are the same material with the same thickness.

Interposer 31 and stiffener 41 are attached onto first dielectric layer 21 through adhesive 131 that contacts and is sandwiched between interposer 31 and first dielectric layer 21 and between stiffener 41 and first dielectric layer 21, and are spaced from each other by stopper 113 and bond pads 111 of coreless substrate 20 between interposer 31 and stiffener 41. Stopper 113, bond pads 111, and placement guide 115 extend from first dielectric layer 21 in the upward direction, wherein stopper 113 is in close proximity to peripheral edges of interposer 31, bond pads 111 are located between peripheral edges of stopper 113 and inner walls of stiffener 41, and placement guide 115 is in close proximity to peripheral edges of outer walls of stiffener 41. Adhesive 131 contacts and is coplanar with stopper 113, bond pads 111, and placement guide 115 in the downward direction and is lower than stopper 113, bond pads 111, and placement guide 115 in the upward direction.

As shown in FIG. 1J, semiconductor assembly 110 is accomplished with bond wires 321 that electrically connect bond pads 111 of the coreless substrate 21 and bond fingers 316 of the interposer 31, and with semiconductor chip 51 flip mounted on first surface 311 of interposer 31 through solder bumps 61 on first contact pads 312 of interposer 31. First conductive traces 241 of coreless substrate 20 directly contact second contact pads 314 of interposer 31. First conductive traces 241 also directly contact bond pads 111, and bond pads 111 of coreless substrate 21 electrically connect to bond fingers 316 of interposer 31 through bond wires 321. Thus, the electrical connection between interposer 31 and coreless substrate 20 is flexibly retained by a combination of bond wires 321 and first conductive micro-vias 243 and is devoid of solder. Accordingly, after flip chip assembly, semiconductor chip 51 can be routed to coreless substrate 20 by first contact pads 312, conductive through-vias 318 and second contact pads 314 of interposer 31 followed by mircro-via connection to coreless substrate 20 and simultaneously by bond fingers 316 of interposer 31 followed by wire-bonding connection to coreless substrate 20.

FIG. 1K is a cross-sectional view of three dimensional assembly 210 with another semiconductor chip 53 attached on coreless substrate 20. Semiconductor chip 53 is aligned with the placement location of interposer 31 and electrically coupled to coreless substrate 20 via solder bumps 63 on interconnect pads 284 exposed from opening 293 of solder mask material 291. Accordingly, semiconductor chips 51, 53 can be electrically connected to one another through interposer 31, coreless substrate 20 and solder bumps 61, 63.

Moreover, the rest of interconnect pads 284 exposed from openings 293 of solder mask material 291 can accommodate a conductive joint, such as solder bump, solder ball, pin, and the like, for electrical communication and mechanical attachment with another assembly or external components. The solder mask openings 293 may be formed by numerous techniques including photolithography, laser drilling and plasma etching.

### Embodiment 2

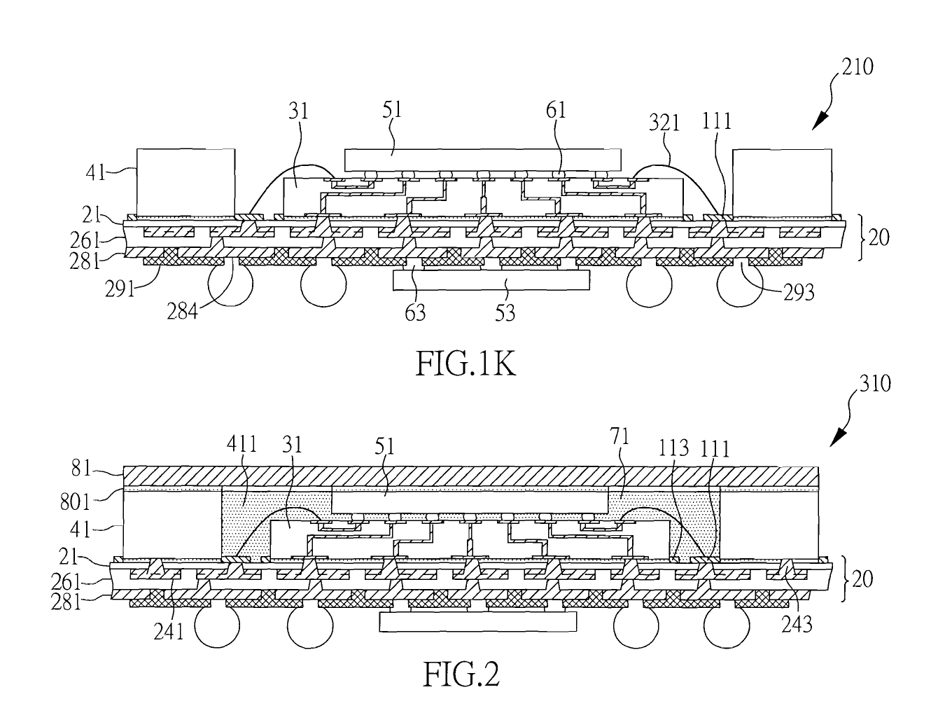

FIG. 2 is a cross-sectional view of another three dimensional assembly 310 with additional first conductive micro-vias 243 that directly contact stiffener 41 for grounding or electrical connection to passive components in accordance with another embodiment of the present invention. Also shown in FIG. 2 are encapsulant 71 and heat dissipating plate 81. Encapsulant 71 such as epoxy fills aperture 411 and covers bond pads 111, stopper 113, first dielectric layer 21, and interposer 31 in the upward direction. Heat dissipation plate 81 such as copper or aluminum is attached onto stiffener 41 and semiconductor chip 51 for assisting heat dissipation via thermally conductive adhesive 801 and covers stiffener 41, encapsulant 71 and semiconductor chip 51 in the upward direction.

The semiconductor assemblies described above are merely exemplary. Numerous other embodiments are contemplated. In addition, the embodiments described above can be mixed-and-matched with one another and with other embodiments depending on design and reliability considerations. For instance, the stiffener can include ceramic material, metal material or epoxy-based laminate, and can have embedded single-level conductive traces or multi-level conductive traces. The stiffener can include multiple apertures to accommodate additional interposers, passive components or other electronic devices and the coreless substrate can include additional conductive traces to accommodate high I/O devices, passive components or other electronic devices.

As shown in the above embodiments, a semiconductor device can share or not share the interposer with other semiconductor devices. For instance, a single semiconductor device can be mounted on the interposer. Alternatively, numerous semiconductor devices can be mounted on the interposer. For instance, four small chips in a 2×2 array can be attached to the interposer and the interposer can include additional contact pads to receive and route additional chip pads. This may be more cost effective than providing an interposer for each chip. Likewise, an aperture of the stiffener can include multiple sets of stoppers to accommodate multiple additional interposers therein and the coreless substrate can include additional conductive traces to accommodate additional interposers. The semiconductor device can be a packaged or unpackaged chip.

Furthermore, the semiconductor device can be a bare chip, or a wafer level packaged die, etc. A semiconductor device can be mechanically and electrically connected to the interposer using a wide variety of connection media including gold or solder bumps. The stopper can be customized for the interposer. For instance, the stopper can have a pattern that defines a square or rectangular area with the same or similar topography as the interposer. External heat dissipation element such as heat spreader or heat sink can be attached to the semiconductor device by thermally conductive adhesive or soldering material. The external heat dissipation element can also be attached to the stiffener to extend the contact area and enhance the efficiency of the dissipation pathway for the semiconductor device.

The term “adjacent” refers to elements that are integral (single-piece) or in contact (not spaced or separated from) with one another. For instance, the first conductive trace is adjacent to the second contact pad but not the first contact pad.

The term “overlap” refers to above and extending within a periphery of an underlying element. Overlap includes extending inside and outside the periphery or residing within the periphery. For instance, in the position that the first contact pads of the interposer faces the upward direction, the stiffener overlaps the dielectric layer since an imaginary vertical line intersects the stiffener and the dielectric layer, regardless of whether another element such as the adhesive is between the stiffener and the dielectric layer and is intersected by the line, and regardless of whether another imaginary vertical line intersects the dielectric layer but not the stiffener (within the aperture of the stiffener). Likewise, the adhesive overlaps the dielectric layer, the stiffener overlaps the adhesive and the adhesive is overlapped by the stiffener. Moreover, overlap is synonymous with over and overlapped by is synonymous with under or beneath.

The term “contact” refers to direct contact. For instance, the conductive trace contacts the second contact pad but not the first contact pad.

The term “cover” refers to complete coverage in a vertical and/or lateral direction. For instance, in the position that the first contact pads of the interposer faces the upward direction, the coreless substrate covers the interposer in the downward direction but the interposer does not cover the coreless substrate in the upward direction.

The term “layer” refers to patterned and un-patterned layers. For instance, the metal layer disposed on the dielectric layer can be an un-patterned blanket sheet before photolithography and wet etching. Furthermore, a layer can include stacked layers.

The terms “opening” and “aperture” refer to a through hole and are synonymous. For instance, in the position that the first contact pads of the interposer faces the upward direction, the interposer is exposed by the stiffener in the upward direction when it is inserted into the aperture in the stiffener.

The term “inserted” refers to relative motion between elements. For instance, the interposer is inserted into the aperture regardless of whether the stiffener is stationary and the interposer moves towards the stiffener, the interposer is stationary and the stiffener moves towards the interposer or the interposer and the stiffener both approach the other. Furthermore, the interposer is inserted (or extends) into the aperture regardless of whether it goes through (enters and exits) or does not go through (enters without exiting) the aperture.

The phrase “aligned with” refers to relative position between elements regardless of whether elements are spaced from or adjacent to one another or one element is inserted into and extends into the other element. For instance, the stopper is laterally aligned with the interposer since an imaginary horizontal line intersects the stopper and the interposer, regardless of whether another element is between the stopper and the interposer and is intersected by the line, and regardless of whether another imaginary horizontal line intersects the interposer but not the stopper or intersects the stopper but not the interposer. Likewise, the first micro-via opening is aligned with the second contact pads of the interposer, and the interposer and the stopper are aligned with the aperture.

The phrase “in close proximity to” refers to a gap between elements not being wider than the maximum acceptable limit. As known in the art, when the gap between the interposer and the stopper is not narrow enough, the location error of the interposer due to the lateral displacement of the interposer within the gap may exceed the maximum acceptable error limit. Once the location error of the interposer goes beyond the maximum limit, it is impossible to align the contact pad with a laser beam, resulting in the electrical connection failure between the interposer and the coreless substrate. According to the pad size of the interposer, those skilled in the art can ascertain the maximum acceptable limit for a gap between the interposer and the stopper through trial and error to prevent the electrical connection failure between the interposer and the coreless substrate. Thereby, the description “the stopper is in close proximity to the peripheral edges of the interposer” means that the gap between the peripheral edges of the interposer and the stopper is narrow enough to prevent the location error of the interposer from exceeding the maximum acceptable error limit.

The phrase “mounted on” includes contact and non-contact with a single or multiple support element(s). For instance, the interposer is mounted on the dielectric layer regardless of whether it contacts the dielectric layer or is separated from the dielectric layer by an adhesive.

The phrase “electrical connection” or “electrically connects” or “electrically connected” refers to direct and indirect electrical connection. For instance, the first conductive trace provides an electrical connection between the interconnect pad and the second contact pad regardless of whether the first conductive trace is adjacent to the interconnect pad or electrically connected to the interconnect pad by the second conductive trace.

The term “above” refers to upward extension and includes adjacent and non-adjacent elements as well as overlapping and non-overlapping elements. For instance, in the position that the first contact pads of the interposer faces the upward direction, the bond pad extends above, is adjacent to and protrudes from the dielectric layer.

The term “below” refers to downward extension and includes adjacent and non-adjacent elements as well as overlapping and non-overlapping elements. For instance, in the position that the first contact pads of the interposer faces the upward direction, the coreless substrate extends below, is adjacent to and protrudes from the adhesive in the downward direction. Likewise, the coreless substrate extends below the stiffener and the interposer even though it is not adjacent to the stiffener and the interposer.

The “first vertical direction” and “second vertical direction” do not depend on the orientation of the assembly, as will be readily apparent to those skilled in the art. For instance, the first contact pads of the interposer faces the first vertical direction and the second contact pads of the interposer faces the second vertical direction regardless of whether the assembly is inverted. Likewise, the stopper is “laterally” aligned with the interposer in a lateral plane regardless of whether the assembly is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the second contact pads of the interposer faces the upward direction, and the first vertical direction is the upward direction and the second vertical direction is the downward direction in the position that the second contact pads of the interposer faces the downward direction.

The semiconductor assembly according to the present invention has numerous advantages. The semiconductor assembly is reliable, inexpensive and well-suited for high volume manufacture. The stiffener provides the mechanical support, dimensional stability and controls the overall flatness and the thermal expansion of the coreless substrate such that the interposer can be securely connected to the coreless substrate under thermal cycling even though the coefficient of thermal expansion (CTE) between them may be different. The direct electrical connection without solder between the interposer and the coreless substrate is advantageous to high I/O and high performance. Particularly, the stopper can accurately confine the placement location of the interposer and avoid the electrical connection failure between the interposer and the coreless substrate resulted from the lateral displacement of the interposer, thereby improving the manufacturing yield greatly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional packaging techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A semiconductor assembly, comprising:
an interposer that includes a plurality of first contact pads and a bond finger on a first surface and a plurality of second contact pads on a second surface, the first surface faces a first vertical direction, and the second surface faces a second vertical direction opposite the first vertical direction, wherein at least one of the first contact pads is electrically connected to a corresponding one of the second contact pads by a conductive through-via in the interposer;
a semiconductor device flip mounted on the first surface of the interposer and coupled to the first contact pads;
a stiffener that includes an aperture with the interposer extending thereinto;
an adhesive that contacts and is sandwiched between the interposer and a coreless substrate; and
the coreless substrate that covers the adhesive, the interposer and the stiffener in the second vertical direction and includes a bond pad that is electrically connected to the bond finger of the interposer by a bond wire, and further includes a conductive micro-via that electrically connects the second contact pad of the interposer.

2. The semiconductor assembly of claim 1, wherein the electrical connection between the interposer and the coreless substrate is devoid of solder.

3. The semiconductor assembly of claim 1, wherein the bond pad is exposed from the coreless substrate surface in the first vertical direction and laterally extends between peripheral edges of the interposer and side walls of the aperture of the stiffener in lateral directions.

4. The semiconductor assembly of claim 1, wherein the coreless substrate further includes a stopper that is aligned with the aperture of the stiffener and serves as a placement guide for the interposer and is in close proximity to and laterally extends between peripheral edges of the interposer and the bond pad.

5. The semiconductor assembly of claim 1, wherein the coreless substrate further includes a placement guide that is in close proximity to and laterally aligned with and laterally extends beyond the outer peripheral edges of the stiffener.
